(19) United States
(12) Patent Application Publication
(10) Pub. No.: US 2024/0097407 A1
(43) Pub. Date: Mar. 21, 2024

(54) LASER DIODE ASSEMBLY, LIGHTING UNIT AND LASER PROJECTION DEVICE

(71) Applicant: ams-OSRAM International GmbH, Regensburg (DE)

(72) Inventor: Tilman Rügheimer, Regensburg (DE)

(73) Assignee: ams-OSRAM International GmbH, Regensburg (DE)

(21) Appl. No.: 18/262,794

(22) PCT Filed: Feb. 4, 2022
(86) PCT No.: PCT/EP2022/052737

§ 371 Date: Jul. 25, 2023

(30) Foreign Application Priority Data
Feb. 5, 2021 (DE) 102021102799.3

(51) Int. Cl. H01S 5/40; H01S 5/02253

(52) U.S. Cl. CPC H01S 5/4093; H01S 5/02253; H01S 5/4012; H01S 5/4018; H01S 5/4075

(57) ABSTRACT

The invention relates to a laser diode arrangement for a laser projection device, comprising a carrier; a laser diode array arranged on the carrier, comprising a first light group having a plurality of first laser diodes and a second light group having a plurality of second laser diodes, said first light emitting group emitting polarized electromagnetic radiation having a first polarization direction and said second light emitting group emitting polarized electromagnetic radiation having a second polarization direction, said first polarization direction and said second polarization direction being perpendicular to each other, the invention being characterized in that said first light emitting group comprises at least one first laser housing accommodating at least one first laser diode and said second light emitting group comprises at least one second laser housing accommodating at least one second laser diode; and the number of first laser diodes of the laser diode array is at least twice the number of second laser diodes, the first laser diodes and the second laser diodes having a corresponding maximum optical output power; and an electrical wiring for the laser diode array is applied on the carrier such that the current intensity at the first laser diodes is adjustable continuously and independently of the energization of the second laser diodes.

### CROSS-REFERENCE TO RELATED APPLICATIONS

The present application is a national phase entry from International Application No. PCT/EP2022/052737, filed on Feb. 4, 2022, published as International Publication No. WO 2022/167594 A1 on Aug. 11, 2022, and claims priority to German Patent Application No. 10 2021 102 799.3 filed Feb. 5, 2021, the disclosure contents of all of which are hereby incorporated by reference in their entireties.

### FIELD OF THE INVENTION

The present invention relates to a laser diode arrangement, an illumination unit comprising the same, and a laser projection device comprising the illumination unit.

### BACKGROUND OF THE INVENTION

The use of semiconductor light sources to illuminate an imaging system in a projection device, for example a micromirror device (DMD) or a liquid crystal panel, is well known. Compared to large-scale illumination modules with discharge lamps, semiconductor light sources allow more compact assemblies for illumination. In addition to LEDs (LED=Light Emitting Diode), laser diode arrays are used as semiconductor light sources, which are characterized by an improved service life, good energy efficiency and high spectral stability, so that luminous laser projection devices with improved color saturation can be realized.

For extensive coverage of the visible spectrum, in particular for professional laser projection devices in movie theaters, high-quality home theaters and miniaturized projectors for smartphones, separate blue, green or red emitting light source units are provided, which are typically arranged spatially separated and whose emission is combined by means of beam combining optics. In this regard, reference is made to US 2020/0301265 A1 by way of example.

Laser diodes emitting in the blue, green and red part of the visible spectrum differ according to the current state of development with regard to the achievable light yield, whereby laser diodes based on InGaN semiconductors with an emission maximum in the green-yellow part of the visible spectrum tolerate lower current densities than those emitting blue. Furthermore, laser diodes for red light have higher thermal stabilization requirements compared to laser diodes for shorter wavelengths. For these reasons, light-generating devices for laser projectors with a monochromatic light source are usually more economical. These typically use high-power laser diodes emitting in the blue, which feed the blue channel and are also used to excite a wavelength conversion element that delivers electromagnetic radiation in the green and red regions. For gated laser projection devices, blue laser diodes are used to excite spectrally different fluorescent materials, such as phosphor-based materials. For sequential generation of the spectral colors, a rotating component with a fluorescent coating can be used as a wavelength conversion element.

Such a color wheel is disclosed, for example, by DE 10 2010 003 234 A1 of-fenced.

DE 11 2013 004 405 B4 describes an illumination arrangement for a laser projection device with two stationary, spatially separated wavelength conversion elements that are assigned to different spectral ranges. This allows simultaneous emission of radiation in the green and red, which is superpositioned in the further beam path. The two wavelength conversion elements are excited by a laser diode array with two alternately arranged laser diode types which differ with respect to the polarization direction and/or the spectral band of the emitted electromagnetic radiation. A beam splitter optics arranged in the beam path between the laser diode array and the wavelength conversion elements takes advantage of this difference in emission characteristics so that radiation from the first laser diode type is directed exclusively to the first wavelength conversion element and from the second laser diode type exclusively to the second wavelength conversion element. For the blue part of the illumination, DE 11 2013 004 405 B4 suggests for a preferred design to use a third separate light source, which is coupled in the beam path after the wavelength conversion elements by means of a collimating lens system. The optics required to guide the beam results in a complex and large-scale illumination arrangement.

US 20190068936 A1 describes an illumination unit with a blue-emitting laser diode array and a wavelength conversion element for emitting fluorescence radiation. A polarization beam splitter is provided in the beam path emitted from the laser diode array, which directs a portion of the radiation to a diffuser to create a blue channel and directs the remaining portion to the wavelength conversion element. Since the laser diode array emits linearly polarized radiation, a polarization element is provided in the beam path before the polarization beam splitter to rotate the direction of polarization by 90° for a portion of the radiation.

It is an object of the invention to provide a laser diode arrangement which makes it possible to simplify the optics for beam guidance in illumination units of laser projection devices. Furthermore, an improved adaptability of the laser diode arrangement to different illumination units shall be given. Furthermore, an illumination unit with a wavelength conversion element and the laser diode arrangement and a laser projection device receiving the latter are to be mentioned, the optical components of which for beam guidance can be designed to be of small size.

### SUMMARY OF THE INVENTION

The objective is solved by the features of claim 1. Advantageous embodiments of the laser diode arrangement are the subject of the sub-claims, and claims 10 and 11 concern an illumination unit comprising the same and a laser projection device.

The starting point of the invention is a laser diode arrangement comprising a carrier and a laser diode array arranged thereon. The laser diode array comprises a first light group with a plurality of first laser diodes and a second light group with a plurality of second laser diodes, wherein the first light group emits linearly polarized electromagnetic radiation with a first polarization direction and the second light group emits linearly polarized electromagnetic radiation with a second polarization direction, and the first polarization direction and the second polarization direction are perpendicular to each other. Thus, the laser diode arrangement is suitable for use in an illumination unit having a polarization beam splitter that splits radiation into a blue channel and an excitation channel for a wavelength conversion element.

In addition, the laser diode arrangement according to the invention is designed in such a way that the power weighting between the blue channel and the excitation channel can be adjusted without the need for additional optics in the illumination unit receiving the radiation. For this purpose, the first light group comprises at least one first laser housing that accommodates at least one first laser diode, and the second light group comprises at least one second laser housing that accommodates at least one second laser diode. From this modular structure, the number of first laser diodes of the laser diode array is at least twice the number of second laser diodes, wherein the first laser diodes and the second laser diodes have a matching maximum optical output power. This preferably refers to each of the first and second laser diodes, whereby it is particularly advantageous to make the radiation generating subunits of the first and second laser diodes identical. Furthermore, an electrical wiring for the laser diode array is applied to the carrier of the laser diode arrangement according to the invention in such a way that the current intensity at the first laser diodes can be set continuously and independently of the current supply to the second laser diodes.

The laser diode array with first and second laser diodes of the same power and a different number of light sources for the two polarization directions, in combination with a modular housing concept, leads to a simplification in production technology and at the same time realizes the basic setting for the distribution of the radiation intensity for the blue and excitation channels to be illuminated. In a preferred embodiment, the number of first laser diodes is at most five times the number of second laser diodes.

A first embodiment assumes uniform components for the radiation generation with a different orientation on the carrier. Consequently, the first laser diode and the second laser diode are identical in construction and, accordingly, the first laser housing and the second laser housing are designed in an overlapping manner, whereby in each case there is a housing axis which determines the polarization direction. Therefore, the first laser housings assigned to the first light group are arranged on the carrier in such a way that their housing axes are perpendicular to those of the second laser housings for the second light group, so that the orthogonality of the polarization directions is given.

For an advantageous second embodiment, the first laser diode and the second laser diode differ with respect to the semiconductor layer sequence or the optical structure, so that a different polarization direction of the emitted radiation results from the internal design. Alternatively, the polarization direction can be caused by adjusting the optics on the laser housings. The use of different types of laser diodes results in simplified wiring for the components on the carrier, which then do not have to be rotated.

Preference is given to an embodiment in which the laser housings each accommodate one laser diode. Typically, there is also one protective diode per laser housing. If vertical emission from the laser housing is also provided, a microlens for collimation of the divergent laser radiation can be assigned to each laser housing for a simplified assembly unit. For one variant, a microlens array that is stationary relative to the common carrier spans the laser diode array as a whole. This allows the laser diode and its associated laser housings to be created in a simplified manufacturing process.

For a preferred alternative embodiment, a laser housing comprises several laser diodes, which are advantageously of identical design. The associated collimation optics can in turn be connected to the individual laser diodes or integrally with the laser housing. Advantageously, there is one protection diode per laser housing.

For continuous adaptability of the current supplied to the laser diodes, electrodes are led out of the respective laser housings. The wiring connecting to the electrodes on the carrier is designed in such a way that laser diodes from different light groups can be externally controlled independently of one another. If there are several laser diodes per housing, these are preferably energized together. For possible embodiments, further sub-groups of the laser diode array are formed within a light group, for example row- or column-shaped arrangements of laser diodes on the carrier, which emit electromagnetic radiation with a matching polarization direction.

For a continuation of the invention, an illumination unit comprises the laser diode arrangement described above. In addition, a polarization beam splitter, a wavelength conversion element and superposition optics are provided. For the illumination unit according to the invention, the polarization beam splitter is arranged in a beam path originating from the laser diode arrangement and is designed in such a way that the polarized electromagnetic radiation emitted by the first light group is directed with the first polarization direction into a beam path leading to the wavelength conversion element and the polarized electromagnetic radiation emitted by the second light group is fed with the second polarization direction into a blue channel.

Thereby, with the basic setting for the distribution of the luminous intensity to the two channels, due to the at least double number of the first laser diodes compared to the number of the second laser diodes and the approach of a coinciding maximum optical output power for the first and second laser diodes, a stronger basic weighting of the excitation channel for the wavelength conversion element can be determined. With the additional feature, according to which the current intensity at the first laser diodes can be set continuously and independently of the energization of the second laser diodes, a temporally variable power control remains possible, whereby on time average the power consumption does not lead to an inhomogeneous temperature distribution in the laser diode array, so that a thermally stable operation of the laser diode array is simplified. The uniformity of the temperature distribution can additionally be improved by a common heat path formed by the carrier.

According to a further development of the invention, a laser projection device with an imaging system and an illumination unit according to the invention is proposed. This is characterized in particular by a compact size and simplified optics for the illumination unit.

### BRIEF DESCRIPTION OF THE DRAWING

In the following, exemplary variants of the invention are explained in connection with figure representations. These show, in each case schematically, the following:

FIG. 1 shows a first embodiment of the laser diode arrangement according to the invention in plan view.

FIG. 2 shows a laser diode for the first embodiment of the laser diode arrangement according to the invention from FIG. 1 in cross-section.

FIG. 3 shows a light source for a second embodiment of the laser diode arrangement according to the invention in cross-section.

FIG. 4 shows the arrangement of the light sources for the second embodiment of the laser diode arrangement according to the invention in plan view.

FIG. 5 shows the electrical circuitry for the version shown in FIG. 4.

FIG. 6 shows a laser projection device with an illumination system comprising a laser diode arrangement according to the invention.

### DETAILED DESCRIPTION

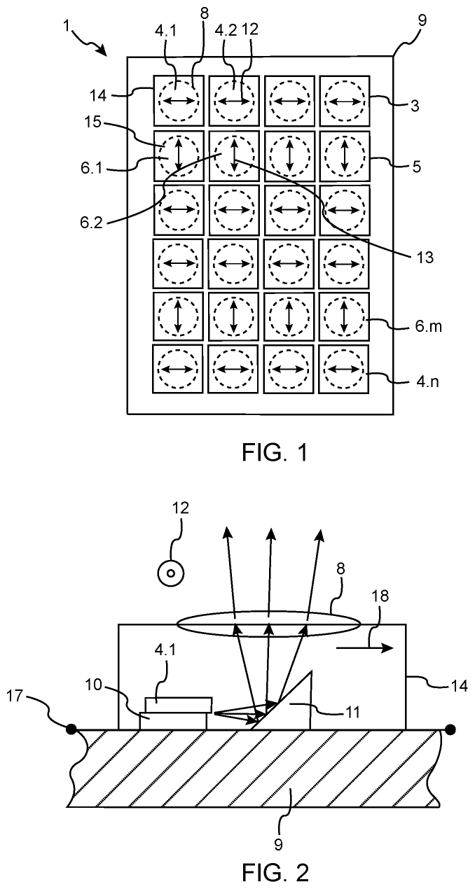

FIG. 1 shows a laser diode arrangement 1 according to the invention with a laser diode array 2 arranged on a common carrier 9. A first light group 3 is evident, which comprises the first laser diodes 4.1, . . . , 4.n arranged in the first, third, fourth and last row. These emit linearly polarized electromagnetic radiation with a first polarization direction 12. A second light group 5 comprising the second laser diodes 6.1, . . . , 6.m arranged in the second and fifth rows of the arrangement emits linearly polarized electromagnetic radiation with a second polarization direction 13. The first polarization direction 12 and the second polarization direction 13 are perpendicular to each other.

Used are first laser diodes 4.1, . . . , 4.n and second laser diodes 6.1, . . . , 6.m with a corresponding maxima optical output power, whereby the number of first laser diodes N of the laser diode array 2 corresponds at least to twice the number of second laser diodes M, so that an asymmetrical radiation intensity results for the emission in the two different polarization directions 12, 13 for the same energization of the laser diodes 6.1, . . . , 4.n; 6.1, . . . , 6.m. It is further advantageous if the number of first laser diodes N of the laser diode array 2 is limited to five times the number of second laser diodes M.

A preferred embodiment of the first laser diode 4.1 arranged in a first laser housing 14 on a submount 10 is sketched in cross-sectional view in FIG. 2. A lateral radiation emission and a beam deflection at a mirror 11 for the formation of a vertical emission in the direction of the surface normal of the carrier 9 are shown. A microlens 8 connected to the first laser housing 14 serves for the collimation of the divergent laser radiation, whereby linearly polarized electromagnetic radiation with the first polarization direction 12 is emitted. The second laser housing 15 and the second laser diode 6.1, . . . , 6.m accommodated therein are designed identically for the first embodiment example, whereby an arrangement on the carrier 9 is made with a rotation of the housing axis 18 by 90°, so that the second polarization direction 13 of the second light group 5 results, which is perpendicular to the first polarization direction 12.

The electrical wiring 16 for the laser diode array 2 is arranged in such a way that the current intensity at the first laser diodes 4.1, . . . , 4.n and correspondingly at those of the second laser diodes 6.1, . . . , 6.m is continuously and in each case independently adjustable. For this purpose, an electrode arrangement 17 is led out of the respective laser housings 14, 15.

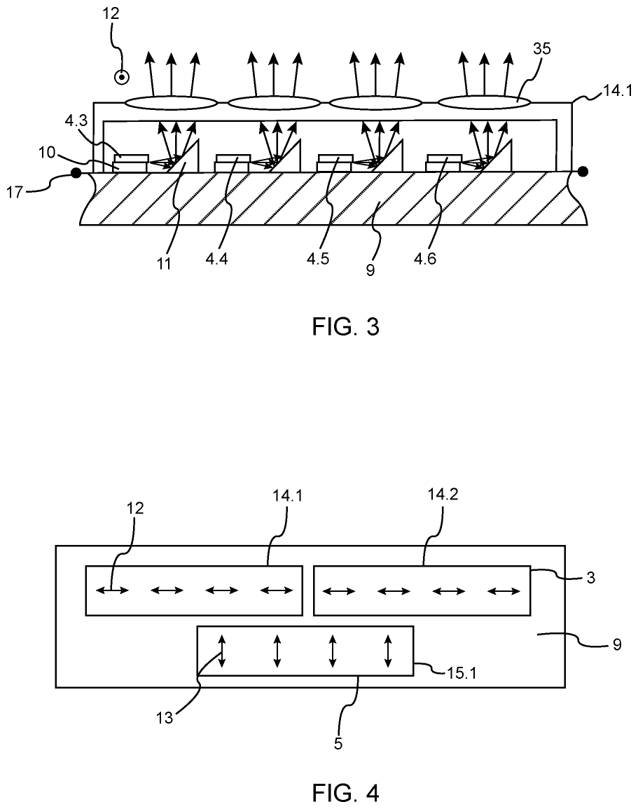

For a preferred second embodiment, the laser diode array 2 comprises modules with several light sources. FIG. 3 shows a first laser housing 14 for receiving the first laser diodes 4.3, . . . , 4.6, each of which emits electromagnetic radiation with the first polarization direction 12. From FIG. 4 it can be seen that inside the first laser housing 14.1, 14.2 and the second laser housing 15.1 there is a different structure, which is selected in such a way that the second polarization direction 13 is perpendicular to the first polarization direction 12. For collimation, a microlens array 19 is used which is stationary with respect to the common carrier 9 and spans the laser diode array 2 as a whole.

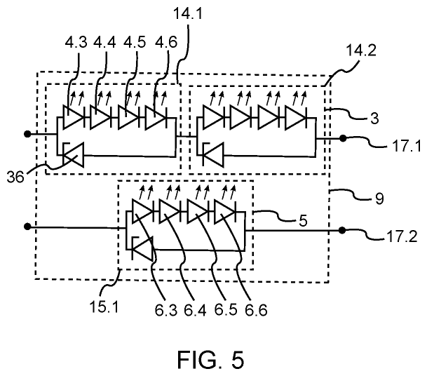

For separate and continuous adjustment of the irradiation of the two light groups 3, 5, the electrode arrangement 17.1, 17.2, as shown in FIG. 5, is led out of the laser housings 14.1, 14.2, 15.1 respectively. Thereby sub-arrays within a light group 3, 5 can be controlled together. Furthermore, a protective diode 36 is provided, which is additionally accommodated in each of the laser housings 14.1, 14.2, 15.1.

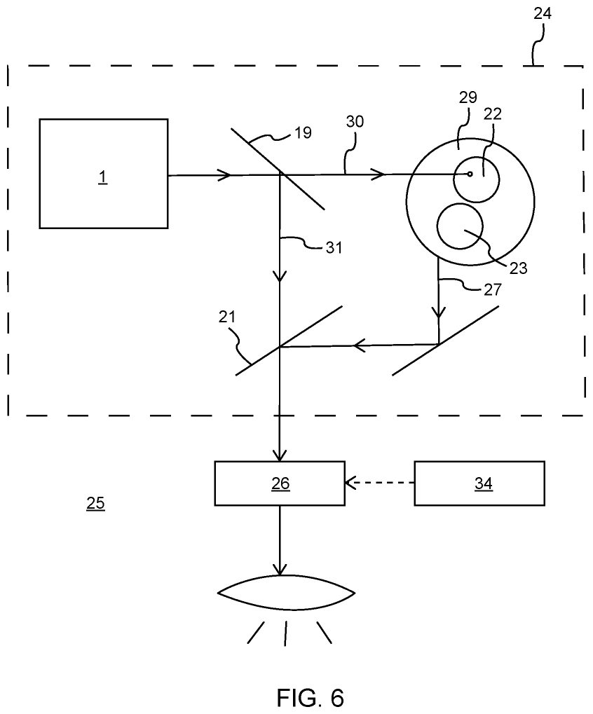

The further design shown in FIG. 6 concerns an illumination unit 24 and its integration into a laser projection device 25. In addition to the laser diode arrangement 1 according to the invention described above, the illumination unit 24 comprises a polarization beam splitter 19, a wavelength conversion element 20 and overlay optics 21, a wavelength conversion element 20 and overlay optics 21. The polarization beam splitter 19 directs the radiation emitted from the laser diode arrangement 1 with the first of the polarization directions to a preferably rotating wavelength conversion element 20, which emits green or red fluorescent radiation 27 by means of the first fluorescent material 22 or the second fluorescent material 23. The radiation portion with the second polarization direction is fed into a blue channel 31 by the polarization beam splitter 19.

In the variant shown, the fluorescent materials 22, 23 are spatially separated from each other. In a modified variant, no spatial separation of the fluorescent materials, such as the first fluorescent material 22 and the second fluorescent material 23, is provided on the conversion element 29 (not shown). In another modified embodiment, a single broadband emitting fluorescent material is used. This may be specifically provided for 3LCD systems in which not one, but three image generators (separated by primary color) are provided and irradiated with a continuously illuminating white light source. The beam paths of the primary colors can be separated by wavelength-selective optics, for example di-chroic mirrors (not shown).

The fluorescence radiation 27 and the radiation from the blue channel 31 are combined into an illumination beam path 32. The illumination unit 24 then passes the radiation to an imaging system 26, which is connected to a controller 34 for projection of an image. Thus, a laser projection device 25 with simplified optics for beam guidance and a compact illumination unit 24 comprising the laser diode arrangement 1 according to the invention for generating differently weighted polarization components results.

1. A laser diode arrangement for a laser projection device, comprising:
a carrier;
a laser diode array arranged on the carrier, comprising a first light group having a plurality of first laser diodes and a second light group having a plurality of second laser diodes,
wherein the first light group emits linearly polarized electromagnetic radiation with a first polarization direction and the second light group emits linearly polarized electromagnetic radiation with a second polarization direction and the first polarization direction and the second polarization direction are perpendicular to one another,
characterized in that
the first light group comprises at least a first laser housing accommodating at least a first laser diode; and
the second light group comprises at least a second laser housing accommodating at least a second laser diode; and
the number of first laser diodes of the laser diode array corresponds to at least twice the number of second laser diodes, wherein the first laser diodes and the second laser diodes comprise a corresponding maximum optical output power; and
an electrical wiring for the laser diode array is arranged on the carrier in such a way that the current intensity at the first laser diodes can be set continuously and independently of the current supply to the second laser diodes.

2. The laser diode arrangement according to claim 1, characterized in that the number of first laser diodes of the laser diode array corresponds to at most five times the number of second laser diodes.

3. The laser diode arrangement according to claim 1, characterized in that the first laser diode and the second laser diode are identical in construction and the first laser housing and the second laser housing are of matching design, wherein in each case a housing axis is present which predetermines the polarization direction, and the first laser housings assigned to the first light group being arranged on the carrier in such a way that their housing axes are perpendicular to those of the second laser housings assigned to the second light group.

4. The laser diode arrangement according to claim 1, characterized in that the first laser diode and the second laser diode have a different structure and/or the first laser housing and the second laser housing are designed differently.

5. The laser diode arrangement according to claim 1,
characterized in that the first laser housing accommodates a single first laser diode and/or the second laser housing accommodates a single second laser diode.

6. The laser diode arrangement according to claim 1,
characterized in that the first laser housing accommodates a plurality of first laser diodes identical in construction and/or the second laser housing accommodates a plurality of second laser diodes identical in construction.

7. The laser diode arrangement according to claims 1,
characterized in that one or more microlenses are associated with each laser housing.

8. The laser diode arrangement according to claims 1,
characterized in that a microlens array, which is stationary relative to the common carrier, spans the laser diode array as a whole.

9. The laser diode arrangement according to claim 1,
characterized in that an electrode arrangement for electrical contacting is guided out of the respective laser housing.

10. An illumination unit comprising:
a laser diode arrangement according to claim 1;
a polarization beam splitter;
a wavelength conversion element; and
a superposition optics,
wherein the polarization beam splitter is arranged in a beam path emitted from the laser diode arrangement and is configured such that the polarized electromagnetic radiation emitted by the first light group is directed with the first polarization direction into a beam path leading to the wavelength conversion element and the polarized electromagnetic radiation with the second polarization direction emitted by the second light group is fed into a blue channel; and
the superposition optics combines fluorescent radiation emitted from the wavelength-conversion element and the radiation from the blue channel into an illumination beam path.

11. A laser projection device comprising an imaging system and an illumination unit according to claim 10 for illuminating an imaging system.
